(19) United States
(12) Patent Application Publication
(10) Pub. No.: US 2026/0061485 A1
(43) Pub. Date: Mar. 5, 2026

(54) System and Method for Sintering Structures on a Base

(71) Applicant: INARI TECHNOLOGY SDN. BHD., Bayan Lepas (MY)

(72) Inventor: Swee Har KHOR, Kuala Lumpur (MY)

(21) Appl. No.: 19/082,102

(22) Filed: Mar. 17, 2025

(30) Foreign Application Priority Data
Aug. 28, 2024 (MY) PI2024005008

(51) Int. Cl. B22F 7/08; H05K 3/40

(52) U.S. Cl. CPC B22F 7/08; B22F 2301/10; H05K 3/40; H05K 2203/1131

(57) ABSTRACT

A system and a method for sintering one or more structures on a base use a sinter unit. The sinter unit is configured to sinter the structures on the base. More specifically, the sinter unit applies force and provides heat to the structures on the base for the structures to sinter, in which a plate is made to be adjacent to the structures on the base.

### FIELD OF INVENTION

The invention generally relates to the fabrication of electronic components. More specifically, a system and method for sintering one or more structures on a base. The structures may be copper pillars and the base may be a substrate such as a wafer.

### BACKGROUND

In the semiconductor industry, copper pillars are fabricated on contacts of an electronic component, such as chips, to provide electrically conductive paths between the electronic component and other components or circuitry. Fabrication of copper pillars conventionally involve electrolytic or electroless plating, which have an inherent problem wherein these plating processes are unable to build up one or more plated copper pillars without any void.

Additionally, these conventional plating processes may not result in copper pillars that are fully solid, and these loosely-plated copper pillars may cause the electronic component to have poor performance.

There are a few disclosed technologies over the prior art relating to the fabrication of copper pillars and their sintering. Among them include the United States Patent Application US20210313197A1. This prior art discloses a system and method for manufacturing conductive pillars using a conductive paste. The conductive paste is applied onto a mask, in the form of a resin film that is formed on a substrate, wherein the resin film comprises a plurality of openings. The conductive paste is made to enter the openings of the resin film to form the conductive pillars. Then, the remaining conductive paste is removed from the surface of the resin film. Subsequently, a sintering process is conducted in a hot environment for conductive pillars to be sintered.

It is to be noted that the teachings of the prior art may have certain weaknesses. In particular, for prior art US20210313197A1, its sintering process is done as the mask (i.e. the resin film) remains on the substrate. As such, the sintered conductive pillars may join to the mask, and as the mask is removed, a certain amount of the sintered conductive material may be removed together with the mask, and the sintered conductive pillars may have a volume that is less than desired. Furthermore, the sintering process may not enable particles of the conductive pillars to be sufficiently sintered as it lacks a force-providing means that enables particles of the conductive pillars to be necked in an even more compact manner.

Evidently, the teachings taught by the aforementioned prior art may not properly enable fabricated copper pillars to be appropriately sintered in a desired manner. Accordingly, it is desirable to have a system and a method that does so.

### BRIEF SUMMARY

Aspects of the invention provide a system and a corresponding method for sintering one or more structures on a base. The system and the corresponding method comprise a sinter unit that applies force and provides heat to the structures on the base for the structures to sinter, in which a plate is made to be adjacent to the structures on the base. The structures that are sintered may be of electrically conductive material such as copper, and the base may be a substrate such as a wafer.

Advantageously, embodiments of the present invention eliminate substrate-level structure formation-related processes such as wafer-level copper pillar formation processes, thereby enabling cycle time improvement in the production process with the benefit of capital expenditure avoidance. Advantageously as well, embodiments of the present invention may provide a more cost-effective alternative for forming copper pillars on wafers compared to existing techniques that form copper pillars on components.

The present invention intends to provide a system for sintering one or more structures on a base, comprising at least one sinter unit, configured to sinter the structures on the base, wherein the sinter unit is further configured to apply force and provide heat to the structures on the base for the structures to sinter, in which a plate is made to be adjacent to the structures on the base.

Preferably, the sinter unit comprises a thermal-pressure module, which comprises a presser, which is configured to apply the force via its press surface, which is further attached with the plate, a platform, in which the base rests thereupon, and a heating sub-module, which is configured to provide heat to any one or both the presser and the platform.

Preferably, the presser, which is attached with the plate, is configured to move along one or more directions, which includes a first direction for applying the force against the structures on the base, with the plate being between the presser and the structures on the base.

Preferably, the presser, which is attached with the plate, is configured to move along a second direction for relieving the force against the structures on the base while leaving the plate on the structures of the base.

Preferably, the system further comprises a plate handler module that is configured to prepare and handle the plate for the plate to be attached onto the presser, the plate to be removed from being rested on the structures of the base, or a combination thereof.

Preferably, the plate has at least one coated layer on at least one of its surfaces for it to adhere to the presser.

Preferably, the system further comprises a first material application unit configured to position a stencil to be adjacent to the base, and dispose or deposit a first material onto the stencil to be spread, for the structures to be formed on the base.

Preferably, the system further comprises a second material application unit configured to dispose or deposit second material onto the structures on the base.

Preferably, the structures are of a material composition that is selected from a group of metals that comprise, but are not limited to, copper, silver, gold, palladium, tin, or platinum.

An aspect of the present invention further provides a method for sintering one or more structures on a base, comprising the step of sintering the structures on the base, by a sinter unit. The sinter unit is further configured to apply force and provide heat to the structures on the base for the structures to sinter, in which a plate is made to be adjacent to the structures on the base.

One skilled in the art will readily appreciate that the invention is well adapted to carry out the objects and obtain the ends and advantages mentioned, as well as those inherent therein. The embodiments described herein are not intended as limitations on the scope of the invention.

### BRIEF DESCRIPTION OF THE DRAWINGS

To facilitate an understanding of the invention, there are illustrated in the accompanying drawings the preferred embodiments from an inspection of which when considered in connection with the following description, the invention, its construction and operation and many of its advantages would be readily understood and appreciated.

FIG. 1 is a schematic diagram illustrating an example system of the present invention for sintering structures on a base.

FIG. 2 is a flowchart illustrating example steps of the method of the present invention for sintering structures on a base.

FIG. 3 is a schematic diagram illustrating the base being applied with a first material, which may be electrically-conductive material, thereupon for forming the first structures on the base, according to an example implementation of the present invention.

FIG. 4 is a schematic diagram illustrating the base having first structures formed thereupon, according to an example embodiment of the present invention.

FIG. 5 is a schematic diagram illustrating the base having the first structures thereon, undergoing drying by a heating module for the first structures to sinter, according to an example implementation of the present invention.

FIG. 6 is a schematic diagram illustrating the base having second structures thereupon, which are sintered from the first structures, according to an example embodiment of the present invention.

FIG. 7 is a schematic diagram illustrating the base having second structures thereupon, which is to receive a pressure force exerted by a heated presser, with a plate being in-between the presser and the second structures, according to an example implementation of the present invention.

FIG. 8 is a schematic diagram illustrating the base having second structures thereupon, in which the plate remains rested on the second structures after the pressure force is relieved, according to an example implementation of the present invention.

FIG. 9 is a schematic diagram illustrating the base having second structures thereupon, in which the plate is removed.

FIG. 10 is a schematic diagram illustrating the base having third structures thereupon, which are sintered from the second structures, according to an example embodiment of the present invention.

FIG. 11 is a schematic diagram illustrating the base having the third structures, each having the second material, being cleaned by one or more cleaners, according to an example implementation of the present invention.

### DETAILED DESCRIPTION

Embodiments of the present invention primarily relate to a system and method for sintering one or more structures on a base. The structures that are sintered may be electrically conductive. More specifically, the structures may be copper pillars.

From hereon, in the context of the present invention, it is to be stated that the term “base” may refer to an item that is to be used as (i) a base layer in which at least one electronic component or electronic circuit is fabricated therefrom, (ii) a base layer that supports at least one electrical and/or electronic component attached thereto, (iii) contact pads of an electronic component that may be a die or a chip, (iv) contact pads of a circuit board, or (v) a combination thereof. The base may broadly also be any form of item that is capable of providing support. It is preferred that the base may be in the form of a substrate, such as a wafer. Furthermore, the base may be electrically conductive, electrically semi-conductive or an electrical insulator. The composition of the base may be of a single element, a compound, an alloy, or a composite. By way of example, the composition of the base may be of silicon, germanium, FR-4, or the like.

Embodiments of the invention will now be described in greater detail, by way of example, with reference to the drawings.

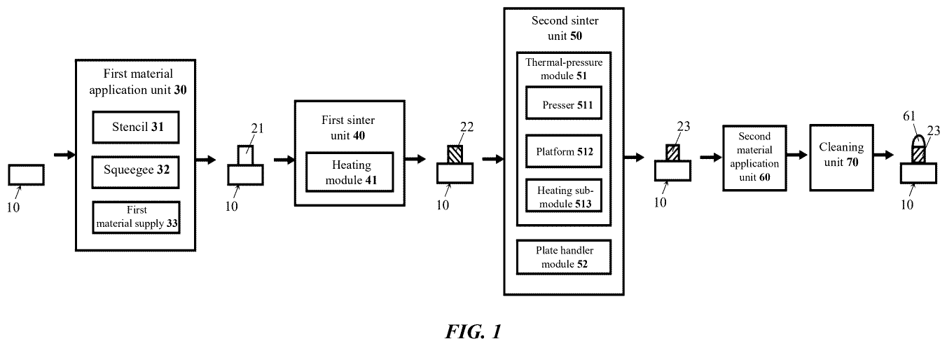

FIG. 1 is a schematic diagram illustrating an example system of the present invention for sintering structures on a base. As shown in FIG. 1, a base 10 is to be provided to the system of the present invention for structures to be formed and sintered thereon.

The system of the present invention may comprise at least one first material application unit 30, at least one first sinter unit 40, at least one second sinter unit 50, at least one second material application unit 60, and at least one cleaning unit 70. It is to be noted that the second material application unit 60, and the cleaning unit 70 may be optionally included in the aforementioned system.

These aforementioned units may be substantially in communication with each other via wired or wireless means. These aforementioned units may also be substantially connected with each other via one or more conveying units which may carry objects (i.e. the base 10 having structures or without structures) from one unit to another. Furthermore, the aforementioned units may be located at different locations, or alternatively, they may be housed within a single machine.

As shown in FIG. 1, the base 10 is to be provided to the first material application unit 30 for one or more first structures 21 to be formed thereon. Then, the base 10, having the first structures 21 thereon, may be provided to the first sinter unit 40 for the first structures 21 to be sintered into second structures 22. Then, the base 10, having the second structures 22 thereon, may then be provided to the second sinter unit 50 for the second structures 22 to be sintered into the third structures 23.

The base 10 having the third structures 23 may then optionally be provided to a second material application unit 60, and subsequently, a cleaning unit 70. With this, the base 10 shall have its third structures 23 disposed or deposited with a second material 61 while being cleaned accordingly for subsequent downstream processing.

Regarding the first material application unit 30 as shown in FIG. 1, it may generally comprise at least one stencil 31, at least one squeegee 32, and at least one first material supply 33 that supplies first material. In particular, the first material supplied by the first material supply 33 is to be disposed or deposited onto the base 10 and be spread across a stencil 31 through the squeegee 32 for filling apertures of the stencil 31. The squeegee 32 may apply a force to ensure that the apertures of the stencil 31 are each compactly filled with the first material. With that, the base 10 may be formed with the first structures 21. It is to be noted that stencil 31 may be made from metallic material, or any other suitable material.

Regarding the first material application unit 30, in one embodiment where the base 10 has one or more contact pads, the stencil 31 may be positioned for its apertures to be aligned with these contact pads so that the first material to be disposed or deposited thereon for the first structures 21 to be formed upon each contact pad.

Whilst not shown in FIG. 1, the first material application unit 30 may generally further comprise at least one manipulator module and at least one processor. In particular, the manipulator may manipulate any one or a combination of the substrate 10, the stencil 31, the squeegee 32 and the first material supply 33 for their intended operations. Whereas, the processor may run at least one software application to operate one or more software modules that execute instructions related to the operation of the first material application unit 30, and it may be substantively interfaced with any one or a combination of the manipulator and the first material supply 33.

Regarding the first sinter unit 40 as shown in FIG. 1, it may generally comprise a heating module 41 that is configured to heat an enclosed environment. Whilst not shown in FIG. 1, the first sinter unit 40 may generally further comprise an accessible enclosure, which may define the enclosed environment especially when it is in a closed condition. The heating module 41 may further be configured to provide heat to the enclosure either by means of conduction, convection, radiation, or any combination thereof. Also, the heating module 41 may further be configured to substantially enable the enclosure to be evenly heated to a preset temperature.

Regarding the second sinter unit 50 as shown in FIG. 1, it may generally be configured to sinter the second structures 22 on the base 10 into the third structures 23. In particular, it may be further configured to apply force and provide heat to the structures (i.e. the second structures 22) on the base 10 for them to sinter, in which a plate 521 is made to be adjacent to the structures on the base 10.

Regarding the second sinter unit 50 as shown in FIG. 1, it may generally comprise a thermal-pressure module 51 and a plate handler module 52. In particular, the thermal-pressure module is configured to provide heat while exerting a force, in the form of a pressure force, to an object (i.e. the base 10 having the second structures 22) that is provided to the second sinter unit 50. Whereas, the plate handler module 52 is to handle a plate that is to be used as an intermediary layer between the aforementioned object and the thermal-pressure module 51.

Regarding the thermal-pressure module 51 as shown in FIG. 1, it may generally comprise a presser 511, a platform 512, and a heating sub-module 513. In particular, the presser 511 is configured to apply the pressure force via its press surface, the platform is where the object (i.e. the base 10 having the second structures 22) rests thereupon, and the heating sub-module 513 is configured to provide heat to any one or both the presser 511 and the platform 512.

In particular, regarding the presser 511, it may be configured to move along one or more directions. These directions may include any one or both a first direction and a second direction. As the presser 511, attached with the plate, moves along the first direction, it applies the pressure force against the structures on the base 10, with the plate being between the presser 511 and the second structures 22 on the base 10. As the presser 511, attached with the plate, moves along the second direction, it relieves the pressure force applied against the second structures 22 on the base 10.

In particular, regarding the presser 511, it is to be noted that its press surface may be substantially smooth for it to be attached to the plate. The shall ensure a maximum transfer of pressure force and heat energy by the presser 511 to the plate attached thereto, for the pressure force and heat energy to be received by the second structures 22 on the base 10 with minimal losses.

In particular, regarding the heating sub-module 513, it may further be configured to substantially heat either one or both the presser 511 and the platform 512 evenly or unevenly to a preset temperature. Also, the heating sub-module 513 may heat the presser 511 and the platform 512 for them to have a different temperature, or a temperature of the same.

Regarding the plate handler module 52 as shown in FIG. 1, it preferably facilitates the handling of a plate that is to be attached onto the press surface of the presser 511. This is so that the plate may be the presser 511 and the object (i.e. the base 10 having the second structures 22) resting on the platform 512, in which the plate is adjacent to the second structures 22 of the base 10. Whilst not shown, the plate handler module 52 may comprise its own manipulator module for preparing and handling the plate for it to be attached to or detached from the presser 511.

Regarding the plate handler module 52, it is to be noted that the characteristics of the plate may include that it is substantially rigid and heat resistant. As such, when the heated presser 511, which is attached with the plate, exerts a pressure force towards the object (i.e. the base 10 having the second structures 22) on the platform 512, the plate may substantially maintain its shape while providing the pressure force and the transfer of heat to the second structures 22. The plate may also have a thickness that shall enable it to withstand the pressure exerted by the presser 511 without undergoing bending or breaking. With this, the plate may be made of material that may be, but shall not be limited to, ceramics, glass, borosilicate glass, polycarbonates, or the like. Moreover, the thickness of the plate may be substantially between 700 μm -900 μm, but most preferably 800 μm, hence, the plate may be wafer-like.

Regarding the plate handler module 52, it is to be noted it may have a coating means, device, or unit, for at least one or both surfaces of the plate to have a coated layer. This may allow the plate to substantially adhere to the press surface of the presser 511 for it to be attached thereon.

In particular, the adhesiveness of the coated layer may be any one or both temperature-dependent and pressure-dependent. Furthermore, it is to be noted that the plate may be pre-coated with the coated layer prior to the second sinter unit 50 receiving an object (i.e. the base 10 having the second structures 22).

It is to be noted that, in one embodiment of the present invention, the plate that is attached onto the presser 511 may detach therefrom, upon the presser 511 having a preset temperature. In yet another embodiment of the present invention, the plate that is attached onto the presser 511 may detach therefrom, upon the presser 511 exerting a preset pressure force upon the object (i.e. the base 10 having the second structures 20) on the platform 512. In yet another embodiment of the present invention, the plate that is attached onto the presser 511 may detach therefrom, upon the presser 511 having a preset temperature and exerting a preset pressure force upon the object (i.e. the base 10 having the second structures 20) on the platform 512.

It is to be noted that, as the heated press 511, which is attached with the plate, exerts a pressure force and provides heat to the object (i.e. the second structures 22 on the base 10) on the platform 512, with the plate being therebetween them, these second structures 22 may undergo sintering and may substantially stick to either one or both the plate and the base 10, instead of the presser 511.

Whilst not shown, the second sinter unit 50 may further comprise a processor that may run at least one software application to operate one or more software modules that execute instructions related to the operation of the second sinter unit 50, and it may be substantively interfaced with, or allows interfacing of, any one or a combination of the thermal-pressure module 51 and the plate handler module 52, and their related components.

Regarding the second material application unit 60 as shown in FIG. 1, it is configured to dispose or deposit second material upon an object (i.e. the third structures 23 of the base 10) that is provided thereto. Whilst not shown, it may substantially comprise components similar to the first material application unit 30. By way of example, it may generally comprise a second material disposition means, a second material supply, and a corresponding processor that operates software modules for its intended operations.

Regarding the cleaning unit 70 as shown in FIG. 1, it is configured to perform cleaning upon at least one object (i.e. the base 10 having the third structures 22 each disposed or deposited with a second material) that is provided thereto. The cleaning unit 70 may generally comprise one or more cleaners 71 for cleaning the entirety of the object. The cleaning performed by these cleaners 71 may be any type of cleaning known in the art of cleaning semiconductor components during their manufacturing.

With this, it is to be noted that the first material that is applied by the first material application unit 30 onto the base 10 is preferably electrically conductive. The composition of the first material may be of a single element, and it may most preferably be copper, but it may be any other element selected from a group of elements that comprise aluminium, silver, gold, palladium, tin, platinum, or the like, and it should be noted that they may not be limited to as such. Alternatively, the first material may have a composition that of an alloy, a compound, or a composite.

In the case where the first material has a material composition that is copper, the first structures may be regarded as first copper pillar precursors, the second structures may be regarded as second copper pillar precursors, and the third structures may be regarded as the final product being copper pillars.

With this, it is to be noted that the second material that is applied by the second material application unit 60 onto the third structures 23 on the base 10 may be bonding material having adhesive properties. More specifically, the second material shall substantially promote bonding between third structures 23 on the base 10 and other components or objects. The second material may be bonding agents such as solder, or the like.

As for processors that may be present in each of the units of the system of the present invention, they may be, but shall not be limited to, a conventional processor, application-specific integrated circuit (ASIC), a field-programmable gate array (FPGA), a graphics processing unit (GPU), or a combination thereof.

It is noted that for the rest of the description, the described hardware and software components of the system may not be directly implicated. However, it is to be understood by a skilled person that the descriptions of the hardware and software components above provide support for the rest of the description.

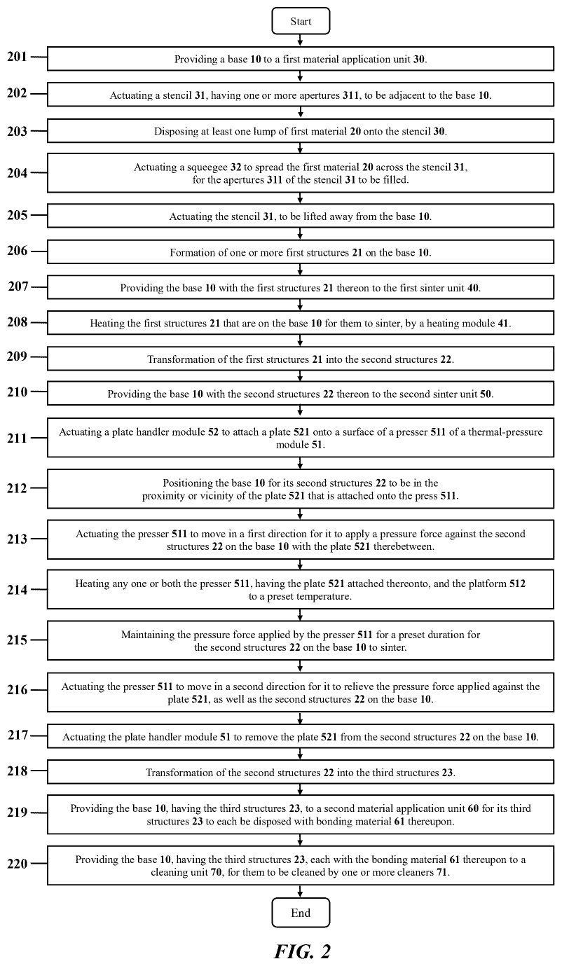

FIG. 2 illustrates an example flowchart describing the method for sintering structures on a base as provided by the present invention. It is noted that the steps described in this flowchart are not to be interpreted as non-limiting, and minor modifications to the steps (e.g. additions, repetitions, omissions, or swaps) are permissible by a skilled person without substantial deviation from as described.

Furthermore, it is to be noted that the descriptions relating to FIG. 2 shall be further complemented by FIG. 3-11, and they may further complement the system of the present invention as described in FIG. 1.

FIG. 2 may begin with step 201. Step 201 may involve providing at least one of the base 10 to the first material application unit 30. In particular, the base 10 had been prepared accordingly for it to be formed with structures. By way of example, base 10 may be a disc of silicon wafer, a piece of silicon die singulated from a silicon wafer, or the like.

Steps 202 to 205 may be subsequent steps of Step 201. Steps 202 to 205 shall be described in relation to FIGS. 2 and 3. More specifically, these steps may relate to operations performed by the first material application unit 30.

In particular, following step 201 may be step 202. Step 202 may involve actuating a stencil 31, having one or more apertures 311, to be adjacent to the base 10.

In particular, following step 202 may be step 203. Step 203 may involve disposing or depositing first material 20 onto the stencil 30. In particular, the first material 20 may be supplied and deposited by the first material supply 33.

In particular, following step 203 may be step 204. Step 204 may involve actuating a squeegee 32 to spread the first material 20 across the stencil 10. While doing so, apertures 311 of the stencil 31 may be filled.

In particular, following step 204 may be step 205. Step 205 may involve actuating the stencil 31 to be lifted away from the base 10.

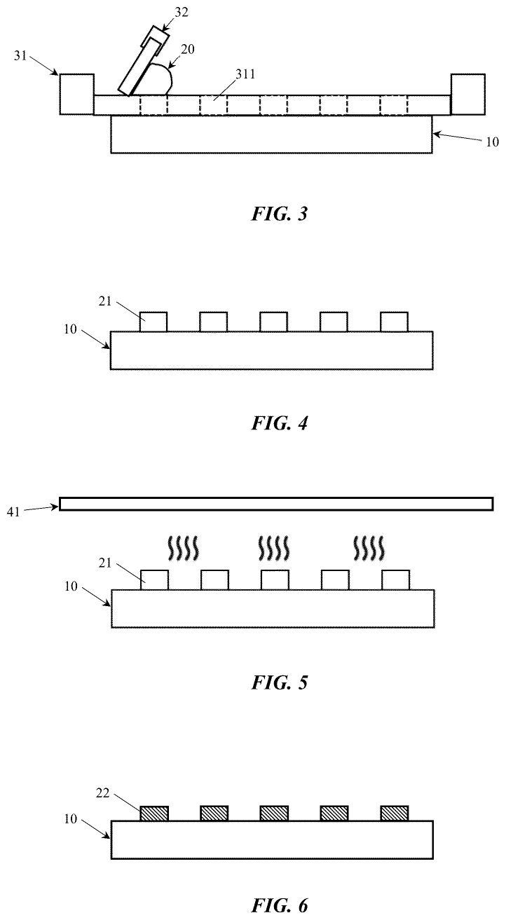

With this, as per step 206 and as shown in FIG. 4, the base 10 shall now be formed with one or more first structures 21 thereon. These first structures 21 may be pillar-like formations on the base 10, wherein the first structures 21 may each have a volume that may correspond to a volume of the apertures 311 of the stencil 31. Following step 206 may be step 207. Step 207 may involve providing the base 10, which has the first structures 21 thereon, to the first sinter unit 40.

Following step 207 may be step 208. Step 208 shall be described in relation to FIGS. 2 and 5. More specifically, step 208 may relate to operations performed by the first sinter unit 40. In particular, step 208 may involve heating the first structures 21 that are on the base 10 for them to dry or sinter, by a heating module 41. In particular, the heating module 41 shall heat the surroundings of the first structures 21.

With this, as per step 209 and as shown in FIG. 6, the base 10 shall now have one or more second structures 22 thereon, which are transformed from, or sintered from, the first structures 21. In particular, these second structures 22 may have shrunk, and each of them may have an overall volume that may be lesser than previous when each of them was in the form of the first structures 21, due to their particles becoming fused after being provided to the first sinter unit 40.

Following step 209 may be step 210. Step 210 may involve providing the base 10, which has the second structures 22 thereon, to the second sinter unit 50.

Steps 211 to 217 may be subsequent steps of Step 210. Steps 211 to 217 shall be described in relation to FIGS. 2, 7, 8 and 9. More specifically, these steps may relate to operations performed by the second sinter unit 50.

In particular, following step 210 may be step 211. Step 211 may involve actuating a plate handler module 52 to attach a plate 521 onto a surface of a presser 511 of a thermal-pressure module 51.

In particular, following step 211 may be step 212. Step 212 may involve positioning the base 10 for its second structures 22 to be in the proximity or vicinity of the plate 521 that is attached onto the press 511.

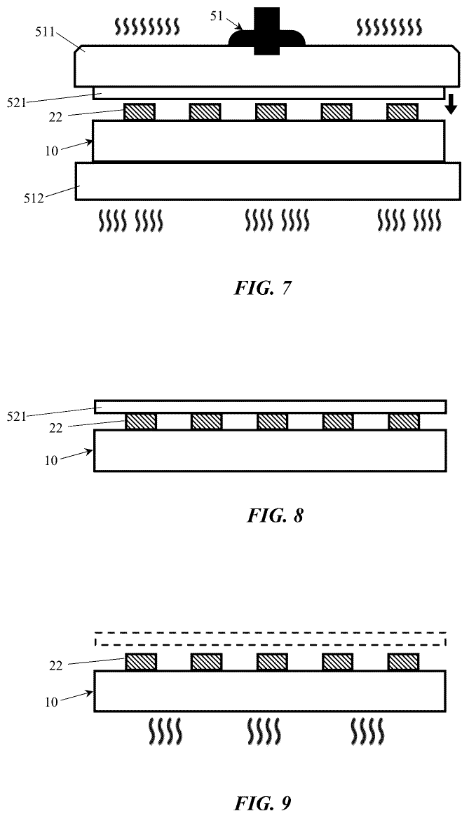

In particular, following step 212 may be step 213. Step 213 may involve actuating the presser 511, having the plate 521 attached thereon, to move in a first direction for it to apply a pressure force against the second structures 22 on the base 10 with the plate 521 being therebetween them. This may be as shown in FIG. 7.

In particular, following step 213 may be step 214. Step 214 may involve heating any one or both (i) the presser 511, having the plate 521 attached thereonto, and (ii) the platform 512, to a preset temperature.

In particular, following step 214 may be step 215. Step 215 may involve maintaining the pressure force applied by the presser 511 for a preset duration for the second structures 22 on the base 10 to sinter.

In particular, following step 215 may be step 216. Step 216 may involve actuating the presser 511 to move in a second direction for it to relieve the pressure force applied against the plate 521, as well as the second structures 22 on the base 10. In particular, as the presser 511 moves in the second direction, the plate 521 is detached from the press surface of presser 511, and shall rest on the second structures 22 on the base 10. This may be as shown in FIG. 8. The plate 521 may remain rested thereon for preset duration.

In particular, following step 216 may be step 217. Step 217 may involve actuating the plate handler module 51 to remove the plate 521 from the second structures 22 on the base 10. This may be as shown in FIG. 9. With this, the plate 521 may either be disposed of, or be reused for a subsequent object that is provided to the second sinter unit 50 in which it may be cleaned and a layer of coating may be applied thereto for its reattachment to the presser 511.

It is to be noted that, in relation to steps 211 to 217, the plate 521 shall prevent the second structures 22 from adhering with the presser 511. As such, the overall shape of the second structures 22 may be substantially maintained or preserved during or after being pressed by the presser 511. Furthermore, the plate 521 may also substantially allow second structures 22 to sinter and join or co-join the base 10, or more specifically, designated locations on the base 10 (e.g. contact pads, etc.), if any.

It is to be noted that, in relation to steps 211 to 217, since the plate 521 is between the presser 511 and the second structures 22 on the base 10, as the presser 511 disengages from the second structures 22, particle adhesion of the second structures 22 to the presser 511 is avoided. As the plate 521 enables the second structures 22 to receive the pressure force exerted by the presser 511, it may also insulate a certain amount of heat transferred from the presser 511 to the second structures 22, thereby avoiding adhesion of upper portions of the second structures 22 onto the plate 521 or the presser 511 during sinter pressing. Hence, no bits/pieces of the second structures 22 will be stuck onto the presser 511, thereby maintaining the overall shape of the second structures 22.

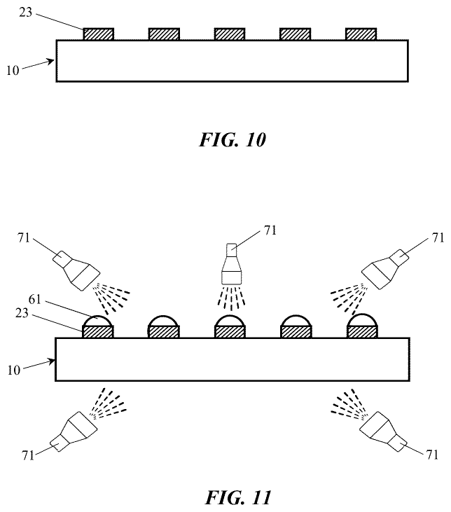

With this, as per step 218 and as shown in FIG. 10, the base 10 shall now have one or more third structures 23 thereon, which are transformed from, or sintered from, the second structures 22. In particular, these third structures 23 may have further shrunk, and each of them may have an overall volume that may be lesser than when they were in the form of the second structures 22. This is due to the second sinter unit 50 further causing the particles of these structures to fuse and become compacted.

Following step 218 may be step 219. Step 219 may involve providing the base 10, having the third structures 23, to a second material application unit 60 for its third structures 23 to each be disposed or deposited with second material 61 thereupon.

Finally, following step 219 may be step 220. Step 220 shall be described in relation to FIGS. 2 and 9. More specifically, step 220 may involve providing the base 10, having the third structures 23, each with the second material 61 thereupon, to a cleaning unit 70, for them to be cleaned by one or more cleaners 71.

In relation to the system described as per FIG. 1, the steps described as per FIG. 2, and the other figures FIG. 3-11, it may be stated that the two or more sinter units (first sinter unit 40 and the second sinter unit 50) consecutively sinters the structures on the base 10 for them to eventually have a desired structural integrity in the form of third structures 23.

With this, a system and method for sintering structures on a base have been described. While it has been described that the invention is generally applicable to items or objects related to the semiconductor fabrication such as fabrication of copper pillars, it is to be noted that the application of the invention may further be generally applicable for other applications that involve sintering structures on a base.

The present disclosure includes as contained in the appended claims, as well as that of the foregoing description. Although this invention has been described in its preferred form, it is understood that the present disclosure of the preferred form has been made only by way of example and numerous changes in the details of the construction, combination and arrangements of parts may be resorted to without departing from the scope of the invention.

What is claimed is:

1. A system for sintering one or more structures on a base, comprising
at least one sinter unit, configured to sinter the one or more structures on the base;
wherein the sinter unit is further configured to
apply force and provide heat to the one or more structures on the base for the one or more structures to sinter, in which a plate is made to be adjacent to the one or more structures on the base.

2. The system according to claim 1, wherein the sinter unit comprises a thermal-pressure module, which comprises
a presser, which is configured to apply the force via its press surface, which is further attached with the plate;
a platform, in which the base rests thereupon; and
a heating sub-module, which is configured to provide heat to any one or both the presser and the platform.

3. The system according to claim 2, wherein the presser, which is attached with the plate, is configured to move along one or more directions, which includes a first direction for applying the force against the one or more structures on the base, with the plate being between the presser and the one or more structures on the base.

4. The system according to claim 3, wherein the presser, which is attached with the plate, is configured to move along a second direction for relieving the force against the one or more structures on the base while leaving the plate on the one or more structures of the base.

5. The system according to claim 4, further comprising a plate handler module that is configured to prepare and handle the plate for
the plate to be attached onto the presser;
the plate to be removed from being rested on the one or more structures of the base;
or a combination thereof.

6. The system according to claim 1, wherein the plate has at least one coated layer on at least one of its surfaces for it to adhere to the presser.

7. The system according to claim 1, further comprising a first material application unit configured to position a stencil to be adjacent to the base, and dispose a first material onto the stencil to be spread, for the one or more structures to be formed on the base.

8. The system according to claim 1, further comprising a second material application unit configured to dispose second material onto the one or more structures on the base.

9. The system according to claim 1, wherein the one or more structures are of a material composition that is selected from a group of metals that comprises copper, silver, gold, palladium, tin, or platinum.

10. A method for sintering one or more structures on a base, comprising the step of sintering the one or more structures on the base, by a sinter unit;
wherein the sinter unit is further configured to
apply force and provide heat to the one or more structures on the base for the one or more structures to sinter, in which a plate is made to be adjacent to the one or more structures on the base.
